(19) United States
(12) Patent Application Publication
(10) Pub. No.: US 2024/0339810 A1
(43) Pub. Date: Oct. 10, 2024

(54) SEMICONDUCTOR ARRAY DEVICE AND SEMICONDUCTOR OPTICAL DEVICE

(71) Applicant: Lumentum Operations LLC, San Jose, CA (US)

(72) Inventor: Masahiro EBISU, Tokyo (JP)

(21) Appl. No.: 18/452,338

(22) Filed: Aug. 18, 2023

(30) Foreign Application Priority Data
Apr. 6, 2023 (JP) 2023-062198
Jun. 21, 2023 (JP) 2023-101753

(51) Int. Cl. H01S 5/042; H01S 5/023; H01S 5/22; H01S 5/40

(52) U.S. Cl. CPC H01S 5/04256; H01S 5/023; H01S 5/22; H01S 5/4031

(57) ABSTRACT

A semiconductor array device includes mesa-stripe structures each including an active layer electrically connected to the semiconductor substrate; individual electrodes each electrically connected to the active layer; and common electrodes each electrically connected to the semiconductor substrate. The mesa-stripe structures include a first mesa-stripe structure and a pair of second mesa-stripe structures, the pair of second mesa-stripe structures sandwiching the first mesa-stripe structure. The common electrodes include a first electrode and a pair of second electrodes, the pair of second electrodes sandwiching the first electrode. The first electrode is closest to the first mesa-stripe structure among the mesa-stripe structures. Each of the pair of second electrodes is closest to a corresponding one of the pair of second mesa-stripe structures among the mesa-stripe structures. Each of the pair of second electrodes is smaller in area than the first electrode.

### CROSS-REFERENCE TO RELATED APPLICATIONS

The present application claims priority from Japan Patent Application number 2023-062198 filed on Apr. 6, 2023 and Japan Patent Application number 2023-101753 filed on Jun. 21, 2023 the contents of which are hereby incorporated by reference into this application.

### TECHNICAL FIELD

The present disclosure relates generally to a semiconductor array device and a semiconductor optical device.

### BACKGROUND

A semiconductor array device can have light-emitting sections that are integrated. Characteristics of the light-emitting sections change due to temperature fluctuations. These temperature fluctuations are influenced by heat generated in adjacent light-emitting sections. For instance, in a semiconductor array device where three light-emitting sections are arranged in a row, the central light-emitting section is affected by heat from both sides, whereas each of the light-emitting sections on the sides is influenced by heat only from one side. Variations in heat quantity cause differences in the effective operating temperatures across the three light-emitting sections, thereby leading to uneven characteristics.

Widths of individual electrodes for respective light-emitting sections can vary depending on their array positions. Specifically, the inner individual electrodes can be wider than outermost individual electrodes. This enables differentiation in the amount of heat dissipation from the individual electrodes, thus minimizing differences in the operating temperatures. However, different widths of individual electrodes leads to different parasitic capacitance, resulting in variability in characteristics.

### SUMMARY

Some implementations described herein minimize differences in characteristics.

In some implementations, a semiconductor array device may include: a semiconductor substrate; mesa-stripe structures that each extend in a first direction, are arranged at equal intervals adjacent to each other in a second direction perpendicular to the first direction, and each include an active layer electrically connected to the semiconductor substrate; individual electrodes that are arranged adjacent to each other in the second direction, and are each electrically connected to the active layer of a corresponding one of the mesa-stripe structures; common electrodes that are arranged adjacent to each other in the second direction, and are each electrically connected to the semiconductor substrate, the mesa-stripe structures including a first mesa-stripe structure and a pair of second mesa-stripe structures, the pair of second mesa-stripe structures sandwiching the first mesa-stripe structure, the common electrodes including a first electrode and a pair of second electrodes, the pair of second electrodes sandwiching the first electrode, the first electrode being closest to the first mesa-stripe structure among the mesa-stripe structures, each of the pair of second electrodes being closest to a corresponding one of the pair of second mesa-stripe structures among the mesa-stripe structures, each of the pair of second electrodes being smaller in area than the first electrode.

In some implementations, a semiconductor optical device may include: the semiconductor array device; and a submount on which the semiconductor array device is mounted, the submount including individual terminals and common terminals, each of the individual terminals being electrically connected to a corresponding one of the individual electrodes, each of the common terminals being electrically connected to a corresponding one of the common electrodes.

### BRIEF DESCRIPTION OF THE DRAWINGS

FIG. 1 is a schematic plan view of a semiconductor array device according to a first example implementation.

FIG. 2 is a II-II cross-sectional view of the semiconductor array device shown in FIG. 1.

FIG. 3 is a schematic plan view of a semiconductor optical device according to the first example implementation.

FIG. 4 is a IV-IV cross-sectional view of the semiconductor optical device shown in FIG. 3.

FIG. 5 is a cross-sectional view of a semiconductor array device according to a second example implementation.

FIG. 6 is a cross-sectional view of a semiconductor array device according to a third example implementation.

FIG. 7 is a diagram of simulation results of how operating temperatures change when a pitch between channels is changed.

FIG. 8 is a cross-sectional view of a semiconductor array device according to a fourth example implementation.

FIG. 9 is a cross-sectional view of a semiconductor array device according to a fifth example implementation.

FIG. 10 is a schematic plan view of a semiconductor optical device according to the fifth example implementation.

FIG. 11 is a XI-XI cross-sectional view of the semiconductor optical device shown in FIG. 10.

FIG. 12 is a schematic plan view of a semiconductor array device according to a sixth example implementation.

FIG. 13 is a XIII-XIII cross-sectional view of the semiconductor array device shown in FIG. 12.

FIG. 14 is a schematic plan view of a semiconductor optical device according to the sixth example implementation.

FIG. 15 is a XV-XV cross-sectional view of the semiconductor optical device shown in FIG. 14.

FIG. 16 is a schematic plan view of a semiconductor array device according to a seventh example implementation.

FIG. 17 is a XVII-XVII cross-sectional view of the semiconductor array device shown in FIG. 16.

### DETAILED DESCRIPTION

The following detailed description of example implementations refers to the accompanying drawings. The same reference numbers in different drawings may identify the same or similar elements. Sizes in the drawings may not correspond to scale.

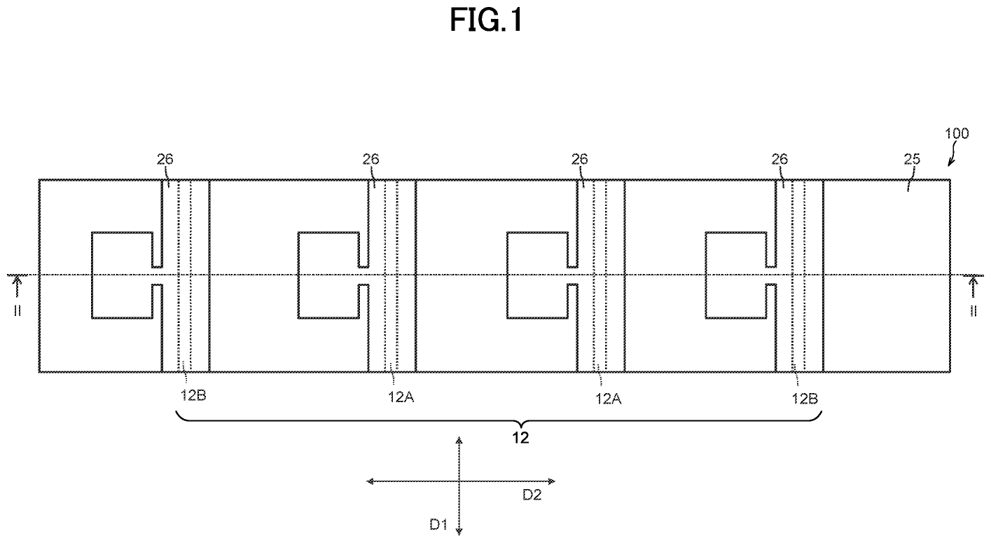

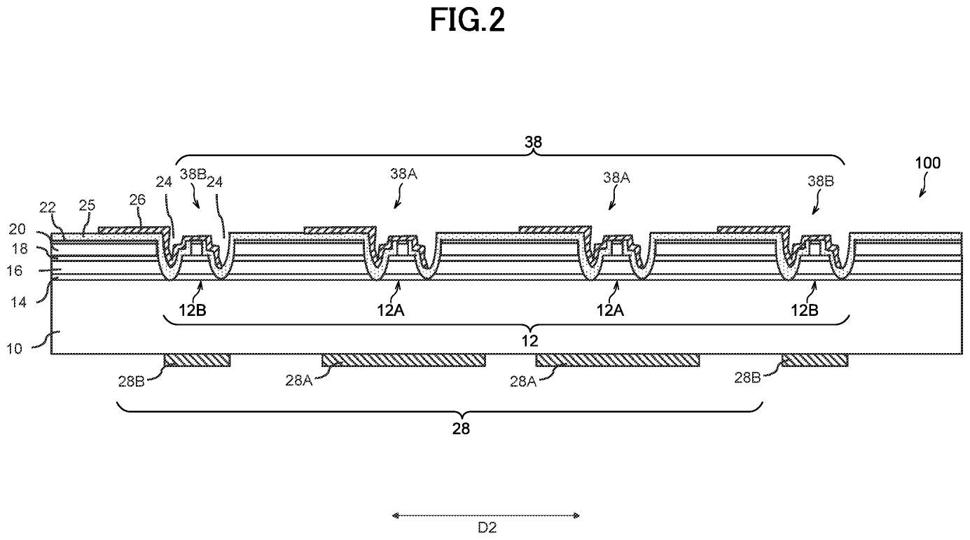

FIG. 1 is a schematic plan view of a semiconductor array device according to a first example implementation. FIG. 2 is a II-II cross-sectional view of the semiconductor array device shown in FIG. 1. The semiconductor array device 100 may be of a ridge type and may be compatible with multiple channels (e.g., four channels).

The semiconductor array device 100 may include a semiconductor substrate 10. The semiconductor array device 100 may include a plurality of mesa-stripe structures 12. The mesa-stripe structures 12 may be on an upper surface of the semiconductor substrate 10. The mesa-stripe structures 12 may extend in a first direction D1 and may be arranged at equal intervals adjacent to each other in a second direction D2 perpendicular to the first direction D1.

Each mesa-stripe structure 12 may include a semiconductor multilayer on the semiconductor substrate 10 of a first conductive type. The semiconductor multilayer may include a buffer layer 14 of the first conductive type, an active layer 16, a mesa etching stop layer 18 of a second conductive type, a clad layer 20 of the second conductive type, and a contact layer 22 of the second conductive type, in sequence from the semiconductor substrate 10. The semiconductor substrate 10 and the buffer layer 14 may each comprise n-type InP. The buffer layer 14 may be omitted. The active layer 16 may have a multiple quantum well structure that may include InGaAlAs or InGaAsP, and may be an undoped layer. Optical confinement layers may be placed above and below the active layer 16. The mesa etching stop layer 18 may comprise p-type InGaAlAs or InGaAsP. The clad layer 20 may comprise p-type InP. A diffraction grating layer may be positioned between the mesa etching stop layer 18 and the clad layer 20. The contact layer 22 may comprise p-type InGaAs. The materials mentioned here are just examples.

Each mesa-stripe structure 12 may be interposed between a pair of separation grooves 24. The distance between the pair of separation grooves 24 may be the width of each mesa-stripe structure 12. The mesa-stripe structures 12 may have equal widths. The mesa-stripe structures 12 and the separation grooves 24 may extend to both end faces of the semiconductor array device 100. The separation grooves 24 may have a depth that reaches at least the buffer layer 14 (e.g., depth that reaches the semiconductor substrate 10).

Each mesa-stripe structure 12 may include an active layer 16 that is electrically connected to the semiconductor substrate 10. By inputting electrical signals, the active layer 16, which may be located at a lower part of each mesa-stripe structure 12 and may be interposed between the pair of separation grooves 24, emits light. The semiconductor array device 100 may be configured to output light from the end face located at the end in the first direction D1, and the output light may be used for optical communications.

A passivation film 25, an insulating film, may be formed on the surface of the semiconductor array device 100. The passivation film 25 may also be located inside the separation grooves 24. The passivation film may not be located on an upper surface of each mesa-stripe structure 12. The passivation film 25 may be, for example, a silicon oxide film or a silicon nitride film.

The mesa-stripe structures 12 may include a first mesa-stripe structure 12A. The first mesa-stripe structure 12A include a plurality of first mesa-stripe structures 12A. The mesa-stripe structures 12 include a pair of second mesa-stripe structures 12B sandwiching the first mesa-stripe structure 12A.

The semiconductor array device 100 may include a plurality of individual electrodes 26. The individual electrodes 26 may be arranged adjacent to each other in the second direction D2. Each individual electrode 26 may be electrically connected to the active layer 16 of a corresponding one of the mesa-stripe structures 12. The individual electrodes 26 may be equal to each other in area and in shape.

The individual electrodes 26 may be in contact with the mesa-stripe structures 12. Each individual electrode 26 may be electrically connected to the contact layer 22. Each individual electrode 26 may be in electrical continuity with the active layer 16 through its corresponding mesa-stripe structure 12. Each individual electrode 26 may include a region extending in the first direction D1 and covering its corresponding mesa-stripe structure 12 and parts of the separation grooves 24, a region positioned on one side of its corresponding mesa-stripe structure 12 in the second direction D2, and a region connecting them.

The semiconductor array device 100 may include a plurality of common electrodes 28. The common electrodes 28 may be on a lower surface of the semiconductor substrate 10. The common electrodes 28 may be arranged adjacent to each other in the second direction D2. The common electrodes 28 may be electrically connected to the semiconductor substrate 10. Each common electrode 28 may be in electrical continuity with the active layer 16 through the semiconductor substrate 10. The common electrodes 28 may be in contact with the semiconductor substrate 10. The common electrodes 28 may be equal in length in the first direction D1.

The common electrodes 28 include a first electrode 28A. The first electrode 28A may include a plurality of first electrodes 28A, separated. The first electrodes 28A may be equal in width. The first electrodes 28A may be equal in area to each other. Each first electrode 28A may overlap with the first mesa-stripe structure 12A. Each first electrode 28A may be closest to its corresponding first mesa-stripe structure 12A.

The common electrodes 28 may include a pair of second electrodes 28B that sandwich the first electrodes 28A. Each second electrode 28B may be an outermost common electrode 28, while each first electrode 28A may be an inner common electrode 28. The pair of second electrodes 28B may be equal in width. Each second electrode 28B may be closest to its corresponding second mesa-stripe structure 12B. Each second electrode 28B may overlap with a closer one of the pair of second mesa-stripe structures 12B. Each second electrode 28B may be equal in length to each first electrode 28A in the first direction D1. Each second electrode 28B may be smaller than each first electrode 28A in width in the second direction D2. Each second electrode 28B may be smaller in area than each first electrode 28A.

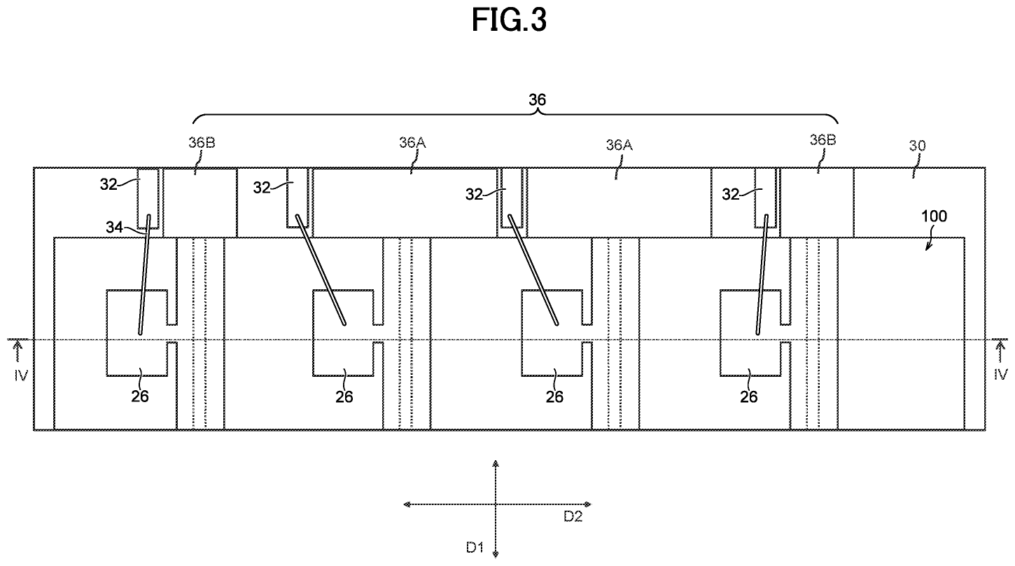

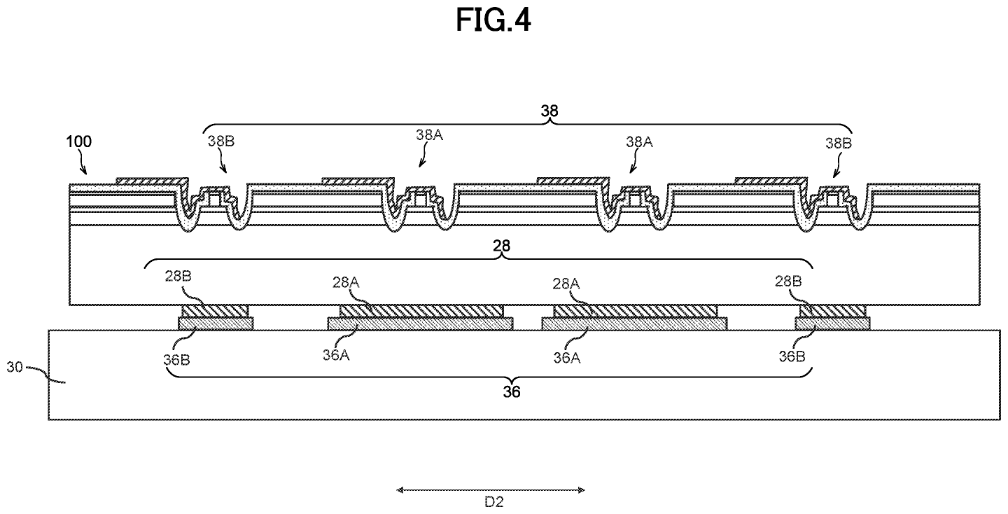

FIG. 3 is a schematic plan view of a semiconductor optical device according to the first example implementation. FIG. 4 is a IV-IV cross-sectional view of the semiconductor optical device shown in FIG. 3. The semiconductor optical device may include the semiconductor array device 100 and a submount 30. The semiconductor array device 100 may be mounted on the submount 30. The mounting method may be junction-up. A substrate of the submount 30 may be formed of ceramics such as AlN.

The submount 30 may include a plurality of individual terminals 32. Each individual terminal 32 may be electrically connected to its corresponding individual electrode 26. The electrical connection may be made by a wire 34.

The submount 30 may include a plurality of common terminals 36. Each common terminal 36 may be electrically connected to its corresponding common electrode 28 and, for example, may be opposed to it for electrical connection. For the electrical connection, a bonding agent such as solder or conductive adhesive may be used. The common terminals 36 may have widths each of which matches the width of its corresponding common electrode 28, but the widths may all be the same.

The common terminals 36 may include a plurality of first terminals 36A opposed to and bonded to the respective first electrodes 28A. The common terminals 36 may include a pair of second terminals 36B opposed to and bonded to the respective second electrodes 28B. Each second terminal 36B may be smaller in area than each first terminal 36A. Each second terminal 36B may be smaller than each first terminal 36A in a bonding area with its corresponding common electrode 28.

Electric signals from an unillustrated external electrical circuit may be input to the common terminals 36 and the individual terminals 32, and transmitted to the common electrodes 28 and the individual electrodes 26 of the semiconductor array device 100, causing light to be generated in the active layers 16, and optical signals are produced. An overlapping area of each common electrode 28 and its corresponding individual electrode 26 may be its corresponding light-emitting section 38. The separation grooves 24 may be present for electrical and optical isolation between adjacent light-emitting sections 38.

When electric signals are input to the semiconductor array device 100, heat may be generated in the light-emitting sections 38. The heat generated in each light-emitting section 38 may be transmitted to its adjacent light-emitting section 38. Each inner light-emitting section 38A may be adjacent to other light-emitting sections 38 on both sides, so heat may be transmitted from both sides. In contrast, the outermost light-emitting section 38B may be adjacent to another light-emitting section 38 on one side only, so heat may be transmitted from one side.

There may be a difference in effective operating temperatures between the inner light-emitting section 38A and the outermost light-emitting section 38B. Specifically, the operating temperature of the outermost light-emitting section 38B may be lower than that of the inner light-emitting section 38A. The difference in operating temperatures may cause variations in characteristics of the light-emitting sections 38. Here, the “operating temperatures” refer to the temperatures of the active layers 16 when electric signals are input to the light-emitting sections 38, and they are in the driven state.

The characteristics of the light-emitting sections 38 may deteriorate as the operating temperatures increase. To increase an amount of heat dissipation, all of the common electrodes 28 should be as large as practical. However, when all of the common electrodes 28 are made equally large, the amount of heat dissipation becomes the same, so the difference in operating temperatures remains unchanged, causing variations in the characteristics of the light-emitting sections 38.

In this example implementation, the heat dissipation for the outermost light-emitting sections 38B may be intentionally reduced. Specifically, each second electrode 28B may be made smaller in area (e.g., in width) than each first electrode 28A. The larger the area (e.g., the width), the greater the amount of heat dissipation. Therefore, each first electrode 28A may have a greater amount of heat dissipation than each second electrode 28B. This may reduce the difference in the effective operating temperatures and may reduce the variation in characteristics between the light-emitting sections 38.

The widths of the common electrodes 28 in contact with the semiconductor substrate 10 may have a strong effect on heat dissipation, but may have little impact on parasitic capacitance and resistance values. Therefore, it may be possible to adjust the amount of heat dissipation while minimizing the variation in characteristics caused by changing the widths. The common electrodes 28 may be connected to the common terminals 36 of the submount 30, and the heat generated in the light-emitting sections 38 may be transmitted to the submount 30 and dissipated.

On the other hand, the individual electrodes 26 may be equal in area (width). The width of the individual electrodes 26 particularly affects the parasitic capacitance. Therefore, if the heat dissipation may be adjusted by changing the area (width) of the individual electrodes 26, variations in frequency response characteristics may occur due to changes in parasitic capacitance, and this may rather increase the variations in characteristics between the light-emitting sections 38. Even when the semiconductor array device 100 is used as a continuous-wave laser (CW laser), changing the area (width) of the individual electrodes 26 affects the contact resistance with the contact layer 22. Variations in resistance values are also a factor causing variations in characteristics, which is not preferable.

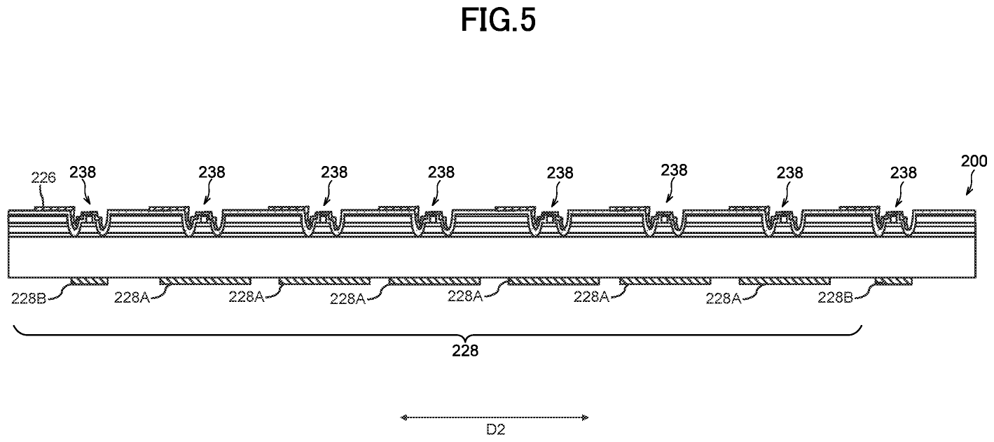

FIG. 5 is a cross-sectional view of a semiconductor array device according to a second example implementation. The cutting position in the cross-sectional view is the same as in the first example implementation. The difference from the first example implementation lies in the number of light-emitting sections 238, and the semiconductor array device 200 may be compatible with eight channels.

The individual electrodes 226 may be equal in width (area). The common electrodes 228 include the outermost second electrodes 228B and the inner first electrodes 228A, and the second electrodes 228B may be smaller in width (area) than the first electrodes 228A. For other configurations, the contents explained in the first example implementation are applicable. The effects of the first example implementation may also be obtained in this example implementation.

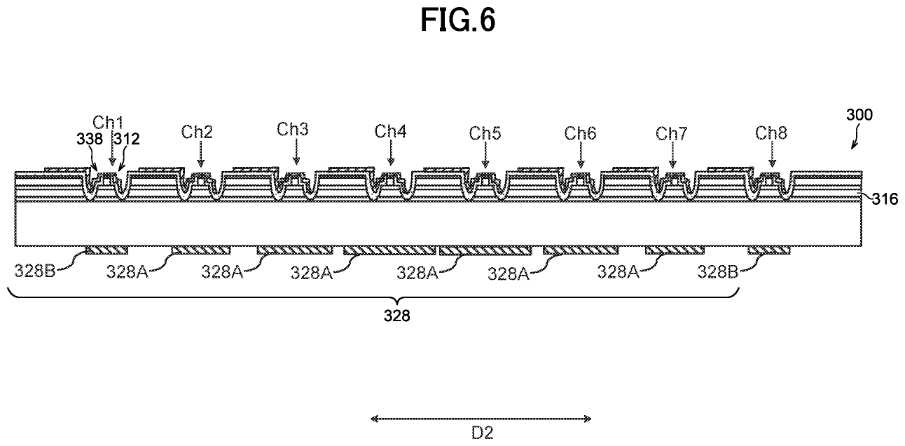

FIG. 6 is a cross-sectional view of a semiconductor array device according to a third example implementation. The cutting position in the cross-sectional view is the same as in the first example implementation. The semiconductor array device 300 may be compatible with eight channels (Ch. 1 to Ch. 8), but the distance (pitch) between the channels may be narrower than in the second example implementation. The pitch between the channels may be defined as the distance between the centers of adjacent mesa-stripe structures 312. The pitch between the channels may be 250 μm in the second example implementation, while it may be 125 μm in this example implementation.

When the pitch between the channels is narrow, heat may be transmitted not only from the adjacent light-emitting section 338 but also from the light-emitting sections 338 that are further apart. Therefore, a closer one of the light-emitting sections 338 to the center of the array may be more affected by the heat. Conversely, a closer one of the light-emitting sections 338 to the outermost part may be less affected by the heat.

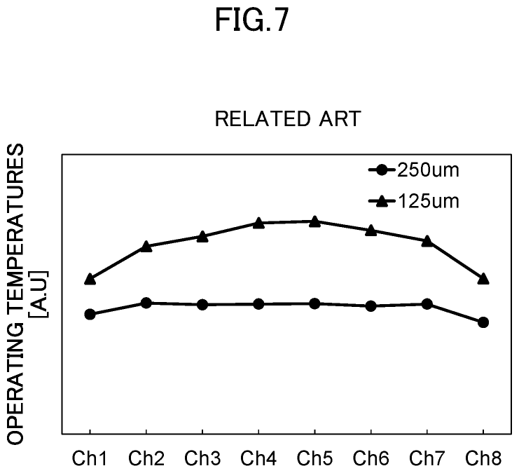

FIG. 7 is a diagram of simulation results of how operating temperatures change when a pitch between channels is changed. The pitches are 250 μm and 125 μm. The operating temperature is the temperature of the active layer 316 in each channel. In the simulation, the widths of all the common electrodes 328 were the same.

As is clear from the simulation results, in the case of the 250 μm pitch, the operating temperatures in Ch. 2 to Ch. 7 are almost the same, and only Ch. 1 and Ch. 8 have lower operating temperatures. In this case, to reduce the difference in operating temperatures, the widths of the second electrodes 328B can be narrowed, as in the second example implementation. On the other hand, when the pitch between channels is 125 μm, the operating temperatures are highest in Ch. 4 and Ch. 5 and gradually decrease towards Ch. 1 and Ch. 8.

Therefore, in this example implementation, by changing the widths of first electrodes 328A according to the degree of the effect of heat, the difference in operating temperatures even between the inner channels may be reduced, thereby reducing the variations in characteristics. Specifically, a closer one of the first electrodes 328A to either of the pair of second electrodes 328B may be smaller in area (width).

The first electrode 328A that is closest to one of the pair of second electrodes 328B may have the same area (width) as the first electrode 328A that is closest to another of the pair of second electrodes 328B. Similarly, the first electrode 328A that is n-th closest to one of the pair of second electrodes 328B may have the same area (width) as the first electrode 328A that is n-th closest to another of the pair of second electrodes 328B.

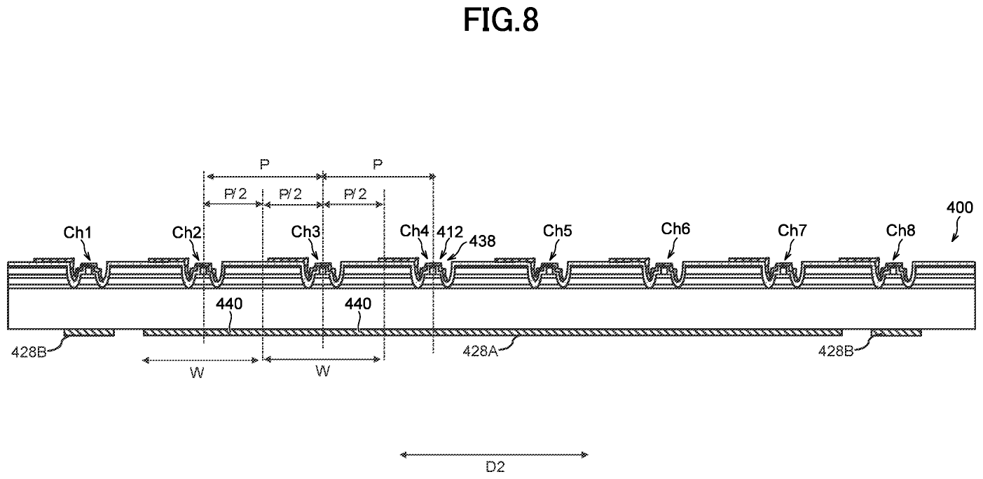

FIG. 8 is a cross-sectional view of a semiconductor array device according to a fourth example implementation. The cutting position in the cross-sectional view is the same as in the first example implementation. The semiconductor array device 400, similarly to the second example implementation, may be compatible with eight channels, and the pitch between channels may be 250μ m.

In the conventional 250 μm pitch, as shown in FIG. 7, the operating temperatures were lower in Ch. 1 and Ch. 8, and equivalent in Ch. 2 to Ch. 7. To improve the overall heat dissipation in Ch. 2 to Ch. 7, the first electrodes 428A may be wider, and it may be preferable to eliminate the spacing between adjacent first electrodes 428A.

In this example implementation, the first electrode 428A may be one first electrode 428A. The one first electrode 428A may include a plurality of sections 440 equal in size to each other and equal in number to the first mesa-stripe structures 412A (light-emitting sections 438). The boundary of the sections 440 may be directly below the midpoint of the adjacent light-emitting sections 438. The width W of each section 440 may be equal to the pitch P of the light-emitting sections 438. In other words, the width W may have a size of half-pitch P/2 on both sides from the midpoint between the adjacent light-emitting sections 438.

Each second electrode 428B may be smaller in area than each section 440. As a result, it may be possible to reduce the temperature difference between channels. Even if the sections 440 are integrated, there may be no temperature difference between the light-emitting sections 438, so there may be no variation in characteristics. The contents explained in the second example implementation may be applicable here.

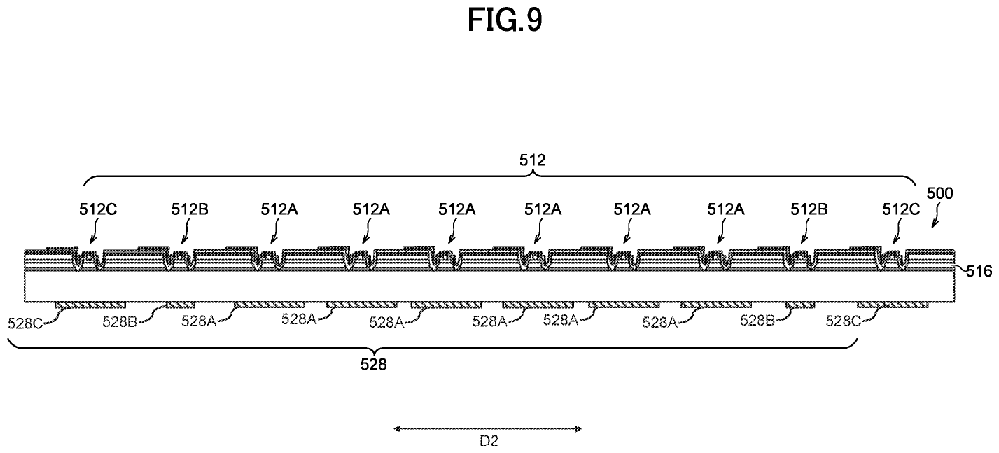

FIG. 9 is a cross-sectional view of a semiconductor array device according to a fifth example implementation. The cutting position in the cross-sectional view is the same as in the first example implementation. The semiconductor array device 500, similarly to the second example implementation, may be compatible with eight channels.

The mesa-stripe structures 512 may include a pair of third mesa-stripe structures 512C. The pair of third mesa-stripe structures 512C may sandwich the first mesa-stripe structures 512A and the pair of second mesa-stripe structures 512B. Each third mesa-stripe structure 512C may be an outermost mesa-stripe structure 512 and may be adjacent to another mesa-stripe structure 512 only on one side. The pair of second mesa-stripe structures 512B may be the inner mesa-stripe structures 512 and may be adjacent to other mesa-stripe structures 512 on both sides. The spacing between the mesa-stripe structures 512 may be uniform.

The common electrodes 528 further include a pair of third electrodes 528C. The pair of third electrodes 528C may sandwich the first electrodes 528A and the pair of second electrodes 528B. Each third electrode 528C may be larger in area than either of second electrodes 528B. Alternatively, the third electrodes 528C may be equal in width to the second electrodes 528B. The third electrodes 528C may be also equal in width to the first electrodes 528A. As explained in the third example implementation, the widths of the first electrodes 528A may be gradually varied.

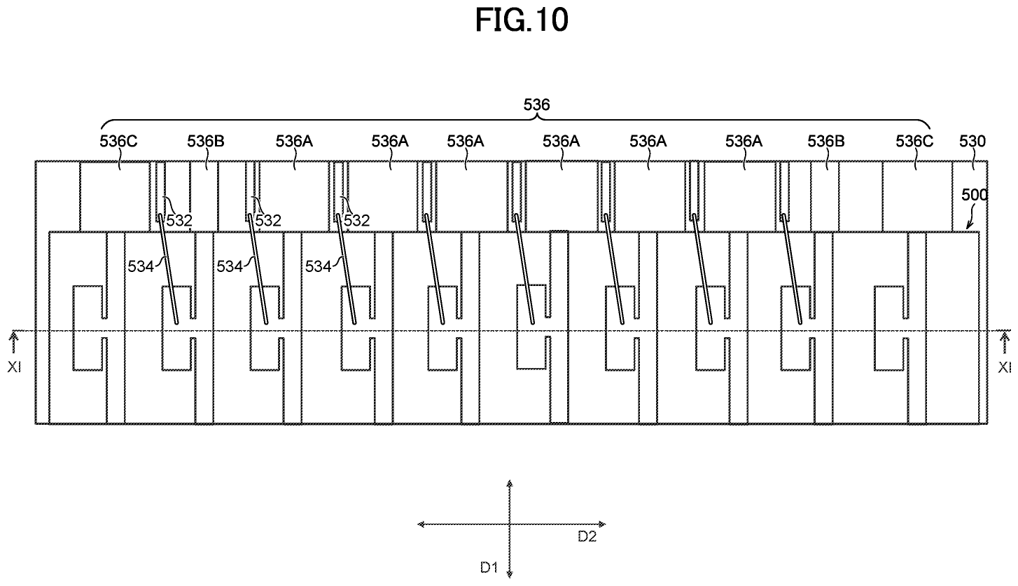

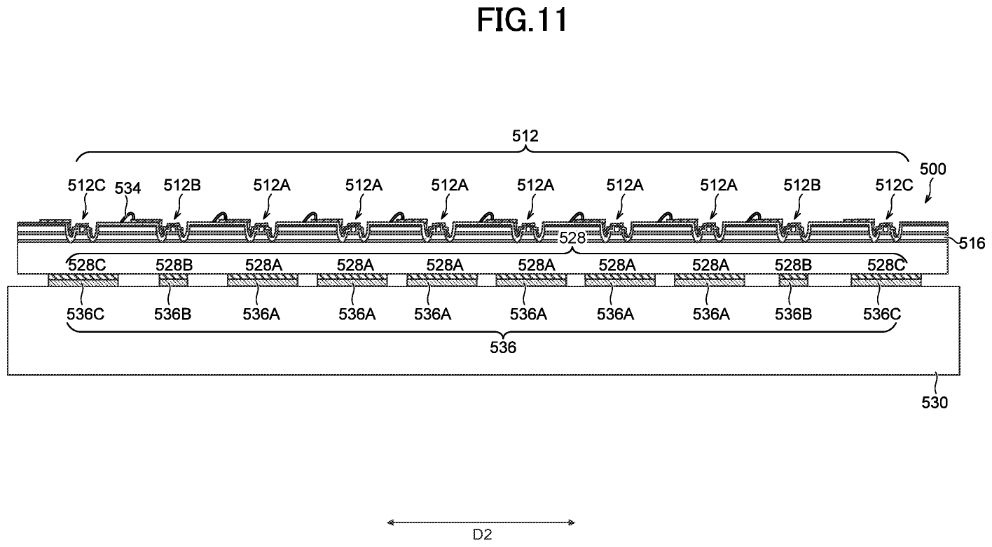

FIG. 10 is a schematic plan view of a semiconductor optical device according to the fifth example implementation. FIG. 11 is a XI-XI cross-sectional view of the semiconductor optical device shown in FIG. 10.

The submount 530 may include a plurality of common terminals 536. The common terminals 536 may include first terminals 536A opposed to and bonded to the first electrodes 528A, a pair of second terminals 536B opposed to and bonded to the respective pair of second electrodes 528B, and third terminals 536C opposed to and bonded to the respective pair of third electrodes 528C.

The submount 530 may include a plurality of individual terminals 532. Each individual terminal 532 (excluding the outermost individual terminals 532) may be electrically connected to the active layer 516 of the first mesa-stripe structure 512A or the second mesa-stripe structure 512B with a wire 534.

No wire may be bonded to the outermost pair of individual terminals 532. The active layer 516 of each third mesa-stripe structure 512C may not be electrically connected to either of the individual terminals 532. Therefore, the outermost third mesa-stripe structures 512C may be dummy structures, and the outermost channels may be non-driving dummy channels. The dummy channels may be equal in structure to the driven channels, but no electrical signal may be input. No light may be emitted from the dummy channels, so no heat may be generated. Therefore, the channels immediately inside the outermost dummy channels may be affected by heat only from one side, making them outermost among the driven channels. In this example implementation as well, the pair of second electrodes 528B may be the same as the pair of second electrodes 528B in other embodiments in the sense that they may be affected by heat only from one side.

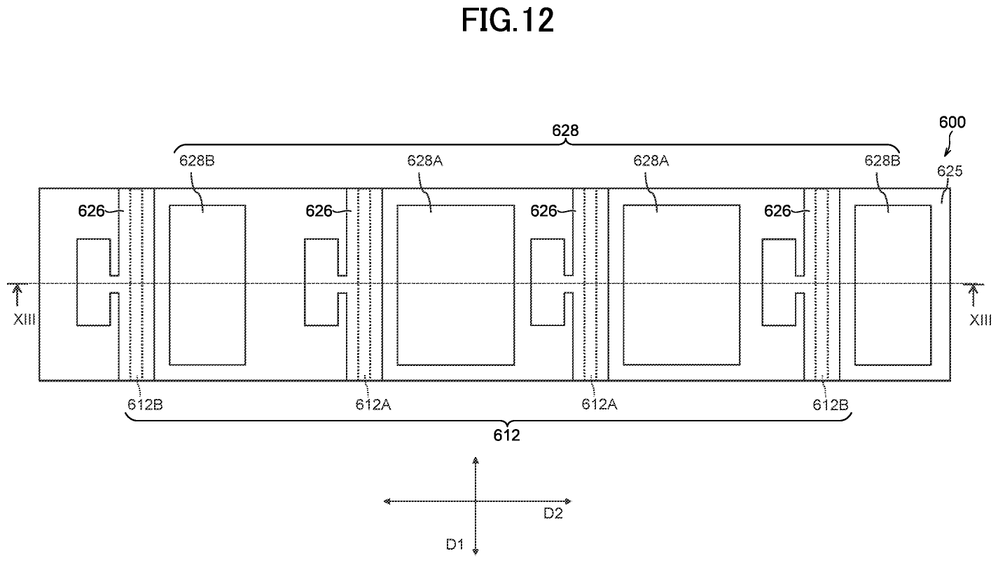

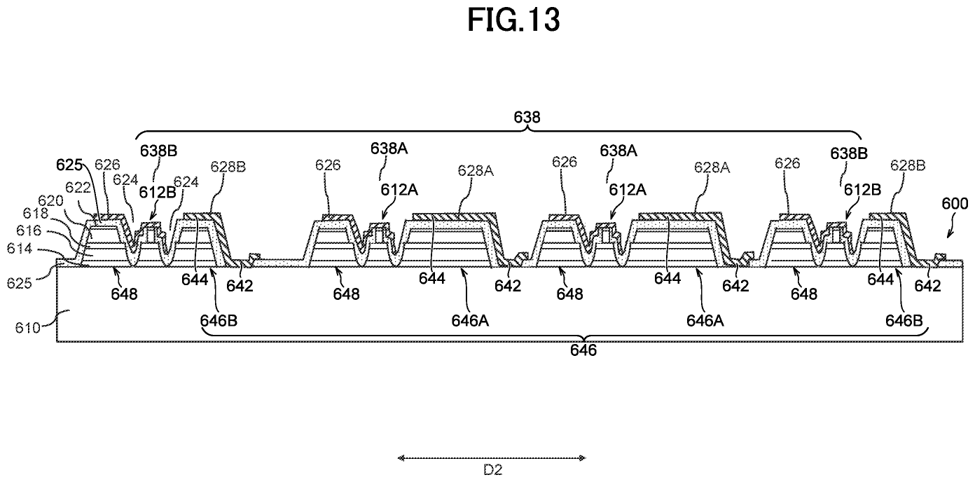

FIG. 12 is a schematic plan view of a semiconductor array device according to a sixth example implementation. FIG. 13 is a XIII-XIII cross-sectional view of the semiconductor array device shown in FIG. 12.

The semiconductor array device 600 may be of the ridge-type, may include four light-emitting sections 638 on the semiconductor substrate 610, and may be compatible with four channels. The mesa-stripe structures 612 may be located at the light-emitting sections 638.

The mesa-stripe structures 612 may be equal in length and width between the pair of separation grooves 624. Each mesa-stripe structure 612 may comprise a semiconductor multilayer on the semiconductor substrate 610 of the first conductive type. The semiconductor multilayer may include a buffer layer 614 of the first conductive type, an active layer 616, a mesa etching stop layer 618 of the second conductive type, a clad layer 620 of the second conductive type, and a contact layer 622 of the second conductive type, in sequence from the semiconductor substrate 610.

The semiconductor substrate 610 and the buffer layer 614 may comprise n-type InP. The buffer layer 614 may be widely formed on the semiconductor substrate 610. Or, the buffer layer 614 may be omitted. The active layer 616 may have a multiple quantum well structure including InGaAlAs or InGaAsP, and may be an undoped layer. Optical confinement layers may be placed above and below the active layer 616. A diffraction grating layer may be placed between the mesa etching stop layer 618 and the clad layer 620. The mesa etching stop layer 618 may comprise p-type InGaAlAs or InGaAsP. The clad layer 620 may comprise p-type InP. The contact layer 622 may comprise p-type InGaAs. The materials listed here are just examples.

A passivation film 625, an insulating film, may be formed on the surface of the semiconductor array device 600. The passivation film 625 may be, for example, an oxide silicon film or a nitride silicon film. The passivation film 625 may be also placed inside the separation grooves 624. The passivation film 625 may not be placed on the upper surfaces of the mesa-stripe structures 612.

On the side where the semiconductor multilayer may be positioned on the semiconductor substrate 610, the common electrodes 628 in contact with the semiconductor substrate 610, and the individual electrodes 626 in contact with the mesa-stripe structures 612 may be arranged.

Each individual electrode 626 may be electrically connected to the contact layer 622. Each individual electrode 626 may be in electrical continuity with the active layer 616 through the mesa-stripe structure 612. Each individual electrode 626 may include a region extending in the first direction D1 and covering the mesa-stripe structure 612 and parts of the separation grooves 624, a region adjacent to the mesa-stripe structure 612 in the second direction D2, and a region connecting them. All four individual electrodes 626 may be equal in area and shape. The four common electrodes 628 may be equal in length in the first direction D1.

The passivation film 625 may not be placed in the regions in contact with the common electrodes 628, on the semiconductor substrate 610. Each common electrode 628 may be in electrical continuity with the active layer 616 through the buffer layer 614 or the semiconductor substrate 610. Each common electrode 628 may be in contact with the buffer layer 614. The buffer layer 614 may be of the same conductive type and formed from the same material as the semiconductor substrate 610, and both may be substantially integral. Each second electrode 628B may be narrower in width than the adjacent first electrode 628A. The pair of second electrodes 628B may be equal in width. The first electrodes 628A may be equal in width.

Each common electrode 628, as shown in FIG. 13, may bend upward from the upper surface of the semiconductor substrate 610, may include the bottom portion 642 in contact with the upper surface of the semiconductor substrate 610, and may include the top portion 644 higher than the bottom portion 642.

Each first electrode 628A may be located adjacent to the first mesa-stripe structure 612A. Each second electrode 628B may be located adjacent to a closer one of the pair of second mesa-stripe structures 612B. The top portion 644 of each second electrode 628B may be smaller in area than the top portion 644 of each first electrode 628A.

On the upper surface of the semiconductor substrate 610, in addition to the mesa-stripe structures 612, there may be a plurality of spacers 646. The spacers 646 may also extend in the first direction D1, may be arranged side by side in the second direction D2, and may comprise a plurality of layers of the same material as the mesa-stripe structures 612.

The spacers 646 may include a first spacer 646A on which the first electrode 628A may be mounted, and a second spacer 646B on which the second electrode 628B may be mounted. The first spacer 646A and the second spacer 646B may be located on the same side (right side in FIG. 13) along the second direction D2 of the mesa-stripe structures 612.

The spacers 646 may include a plurality of individual spacers 648 on which the respective individual electrodes 626 may be mounted. The individual spacers 648 may be located on the same side (left side in FIG. 13) along the second direction D2 of the respective mesa-stripe structures 612. Each individual electrode 626 may include a portion on the mesa-stripe structure 612, a portion on the individual spacer 648, and a portion connecting them.

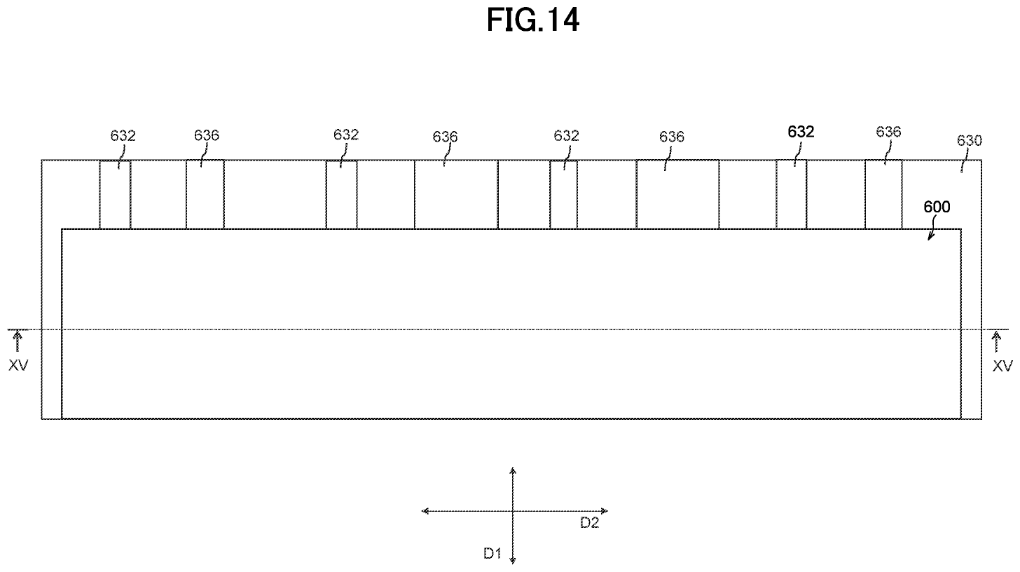

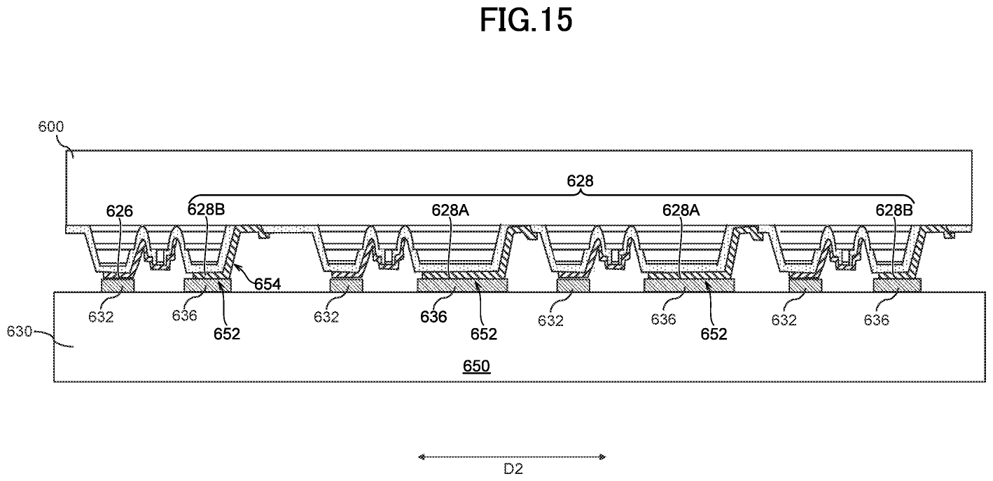

FIG. 14 is a schematic plan view of a semiconductor optical device according to the sixth example implementation. FIG. 15 is a XV-XV cross-sectional view of the semiconductor optical device shown in FIG. 14. The semiconductor array device 600 may be mounted junction-down on the submount 630. The submount 630 may include a substrate 650 comprising ceramic such as AlN. The submount 630 may include a plurality of individual terminals 632 and a plurality of common terminals 636.

Each individual terminal 632 may be opposed to and electrically connected to its corresponding individual electrode 626. They may also be mechanically connected. The individual terminals 632 may be connected to the individual electrodes 626 of the semiconductor array device 600 with solder or conductive adhesive.

Each common terminal 636 may be opposed to and electrically connected to its corresponding common electrode 628. They may be also mechanically connected. The common terminals 636 may be connected to the common electrodes 628 of the semiconductor array device 600 with a bonding agent such as solder or conductive adhesive.

From an unillustrated external electrical circuit, electrical signals may be input to the common terminals 636 and individual terminals 632, and transmitted to the common electrodes 628 and individual electrodes 626, and then light may be generated in the active layer 616, and optical signals may be produced.

In this example implementation, since the outermost light-emitting sections 638B may be less affected by heat than the inner light-emitting sections 638A, the same effect as in the other example implementations may be obtained by making the second electrodes 628B smaller in width than the first electrodes 628A. When the second electrodes 628B are smaller in area than the first electrodes 628A, the lengths in the first direction D1 of both of them may be the same or different.

Each common electrode 628 may include a contact region 652 in contact with the common terminal 636, and a non-contact region 654 not in contact with the common terminal 636. The inner first electrodes 628A may be larger in areas of the contact regions 652 than the outermost second electrodes 628B. Heat dissipation also occurs in the non-contact region 654, but the amount of heat dissipation may be higher in the contact region 652. Therefore, by adjusting the area of the contact region 652, the effect of suppressing differences in the effective operating temperatures between the respective light-emitting sections 638 may be enhanced. Note that the areas of the regions where the individual electrodes 626 and the individual terminals 632 may be in contact may be the same. This may be to prevent variations in characteristics such as parasitic capacitance, as mentioned above.

As shown in this example implementation, the individual electrodes 626 and the common electrodes 628 may be arranged on the same side of the semiconductor substrate 610. In other example implementations, employing a configuration where the common electrodes 628 are positioned on the same side may also achieve similar results.

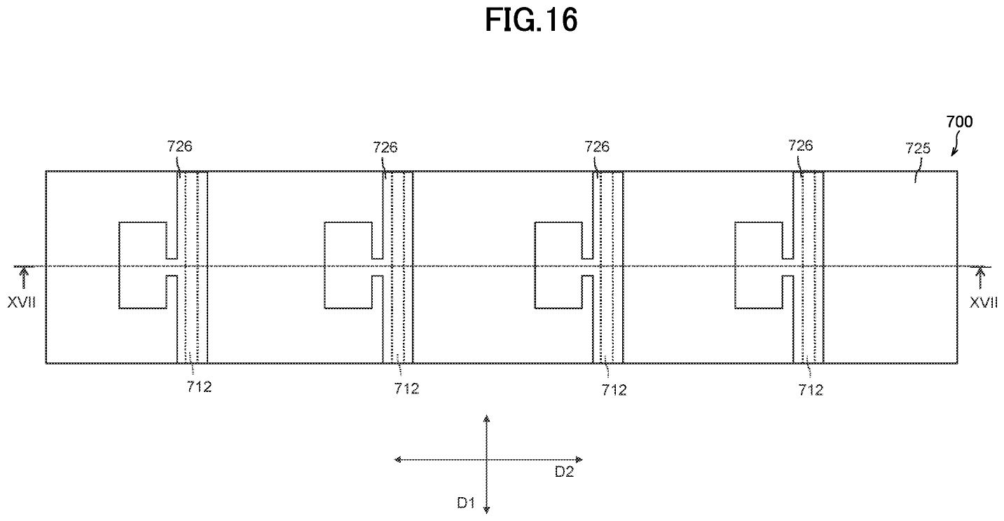

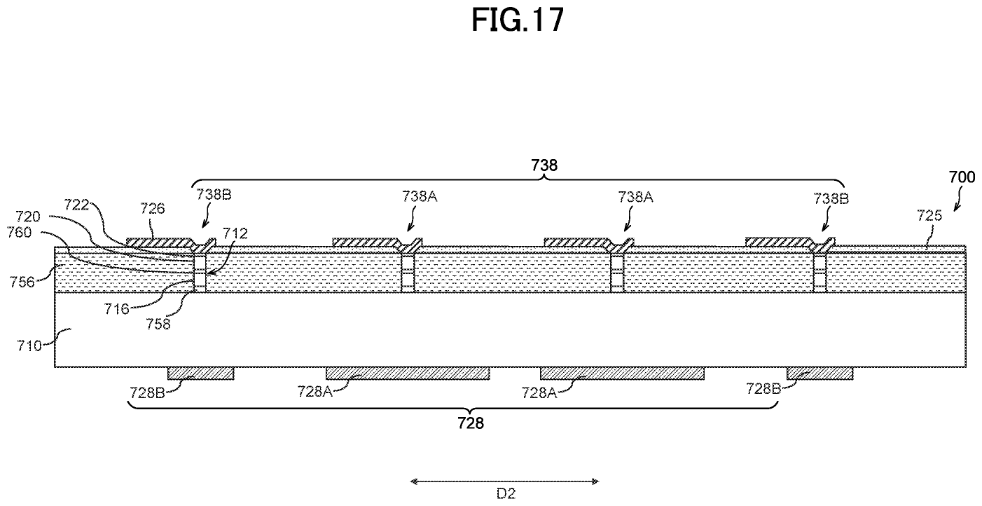

FIG. 16 is a schematic plan view of a semiconductor array device according to a seventh example implementation. FIG. 17 is a XVII-XVII cross-sectional view of the semiconductor array device shown in FIG. 16.

The semiconductor array device 700 may be of buried type, and each mesa-stripe structure 712 may be buried on both sides with a buried layer 756. The buried layer 756 is, for example, comprising semi-insulating InP.

The semiconductor array device 700 may include a plurality of light-emitting sections 738 on the semiconductor substrate 710 and may be compatible with four channels, for example. The mesa-stripe structures 712 may be located at the light-emitting sections 738. At each light-emitting section 738, the common electrode 728 may be in contact with the semiconductor substrate 710, and the individual electrode 726 may be in contact with the mesa-stripe structure 712. The light-emitting sections 738 may be defined by overlapping regions of the common electrodes 728 and the individual electrodes 726. When electrical signals are input, the active layer 716 included in each mesa-stripe structure 712 emits light.

Each individual electrode 726 may include a region that may be wider than the mesa-stripe structure 712 and extends in the first direction D1, a region that may be positioned adjacent to the mesa-stripe structure 712 in the second direction D2, and a region connecting them. The areas of all four individual electrodes 726 may be the same, and shapes of them may be also equal.

The mesa-stripe structures 712 may extend to both end faces of the semiconductor array device 700. The mesa-stripe structures 712 may be equal in width. Each mesa-stripe structure 712 may comprise a semiconductor multilayer on the semiconductor substrate 710 of the first conductivity type. The semiconductor multilayer may comprise an optical confinement layer 758 of the first conductivity type, an active layer 716, an optical confinement layer 760 of the second conductivity type, a clad layer 720 of the second conductivity type, and a contact layer 722 of the second conductivity type, in sequence from the semiconductor substrate 710.

The semiconductor substrate 710 may comprise n-type InP. The optical confinement layer 758, the active layer 716, and the optical confinement layer 760 may comprise InGaAlAs or InGaAsP. The active layer 716 may be an undoped multiple quantum well layer. The clad layer 720 may comprise p-type InP. The contact layer 722 may comprise p-type InGaAs. A buffer layer may be placed between the semiconductor substrate 710 and the optical confinement layer 758. A diffraction grating layer may be placed between the optical confinement layer 760 and the clad layer 720. Note that the materials mentioned here are just examples.

On the surface of the semiconductor array device 700, the passivation film 725, an insulating film, may be formed. The passivation film 725 may be placed except on the upper surfaces of the mesa-stripe structures 712. The passivation film 725 may be a silicon oxide film or a silicon nitride film, for example.

In this example implementation, the inner light-emitting sections 738A may be more greatly affected by heat than the outermost light-emitting sections 738B. Therefore, the second electrode 728B of the light-emitting section 738B, adjacent to only one light-emitting section 738, may be smaller in area (width) than the first electrode 728A of the light-emitting section 738A interposed between a pair of light-emitting sections 738. This may reduce the difference in operating temperatures between the light-emitting sections 738 and reduces the variation in characteristics. Note that combining this with other example implementations may yield the same effects.

If the second electrodes 728B are smaller in area (width) than the first electrodes 728A, their lengths in the first direction D1 may be either the same or different. Both the first electrodes 728A and the second electrodes 728B may be in electrical continuity with the semiconductor substrate 710. On the other hand, due to the strong influence on the characteristics, the areas of the individual electrodes 726 connected to the mesa-stripe structures 712 may be the same.

The example implementations described above are not restrictive, and various modifications are possible. The structures explained in the example implementations may be replaced with structures that are substantially similar or others that can achieve the same effect or purpose.

In a first implementation, a semiconductor array device 100 includes: a semiconductor substrate 10; mesa-stripe structures 12 that each extend in a first direction D1, are arranged at equal intervals adjacent to each other in a second direction D2 perpendicular to the first direction D1, and each include an active layer 16 electrically connected to the semiconductor substrate 10; individual electrodes 26 that are arranged adjacent to each other in the second direction D2, and are each electrically connected to the active layer 16 of a corresponding one of the mesa-stripe structures 12; common electrodes 28 that are arranged adjacent to each other in the second direction D2, and are each electrically connected to the semiconductor substrate 10, the mesa-stripe structures 12 including a first mesa-stripe structure 12A and a pair of second mesa-stripe structures 12B, the pair of second mesa-stripe structures 12B sandwiching the first mesa-stripe structure 12A, the common electrodes 28 including a first electrode 28A and a pair of second electrodes 28B, the pair of second electrodes 28B sandwiching the first electrode 28A, the first electrode 28A being closest to the first mesa-stripe structure 12A among the mesa-stripe structures 12, each of the pair of second electrodes 28B being closest to a corresponding one of the pair of second mesa-stripe structures 12B among the mesa-stripe structures 12, each of the pair of second electrodes 28B being smaller in area than the first electrode 28A.

Since the second electrode 28B is smaller in area than the first electrode 28A, it is possible to reduce the characteristic differences caused by heat. Because both of them are included in the common electrodes 28, they do not cause variations in characteristics due to factors other than heat.

In a second implementation, alone or in combination with the first implementation, each of the pair of second electrodes 28B is equal in length to the first electrode 28A in the first direction D1, and each of the pair of second electrodes 28B is smaller in width W than the first electrode 28A in the second direction D2.

In a third implementation, alone or in combination with one or more of the first and second implementations, wherein the individual electrodes 26 are equal in area to each other.

In a fourth implementation, alone or in combination with one or more of the first through third implementations, wherein the first mesa-stripe structure 412A includes a plurality of first mesa-stripe structures 412A, the first electrode 428A is one first electrode 428A, the one first electrode 428A includes a plurality of sections equal in size to each other and equal in number to the first mesa-stripe structures 412A, and each of the pair of second electrodes 428B is smaller in area than each of the portions.

In a fifth implementation, alone or in combination with one or more of the first through fourth implementations, wherein the first mesa-stripe structure 12A includes a plurality of first mesa-stripe structures 12A, and the first electrode 28A includes a plurality of first electrodes 28A, separated.

In a sixth implementation, alone or in combination with one or more of the first through fifth implementations, wherein the first electrodes 28A are equal in area to each other. In a seventh implementation, alone or in combination with one or more of the first through sixth implementations, wherein a closer one of the first electrodes 328A to either of the pair of second electrodes 328B is smaller in area.

In an eighth implementation, alone or in combination with one or more of the first through seventh implementations, wherein the mesa-stripe structures 12 are on an upper surface of the semiconductor substrate 10, the common electrodes 28 are on a lower surface of the semiconductor substrate 10, the first electrode 28A overlaps with the first mesa-stripe structure 12A, and each of the pair of second electrodes 28B overlaps with a closer one of the pair of second mesa-stripe structures 12B.

In a ninth implementation, alone or in combination with one or more of the first through eighth implementations, wherein the mesa-stripe structures 612 are on the upper surface of the semiconductor substrate 610, the common electrodes 628 are in contact with the upper surface of the semiconductor substrate 610, the first electrode 628A is adjacent to the first mesa-stripe structure 612A, and each of the pair of second electrodes 628B is adjacent to a closer one of the pair of second mesa-stripe structures 612B.

In a tenth implementation, alone or in combination with one or more of the first through ninth implementations, wherein each of the common electrodes 628 bends upward from the upper surface of the semiconductor substrate 610 and includes a bottom portion 642 in contact with the upper surface and a top portion 644 at a higher position than the bottom portion 642, and the top portion 644 of each of the pair of second electrodes 628B is smaller in area than the top portion 644 of the first electrode 628A.

In an eleventh implementation, alone or in combination with one or more of the first through tenth implementations, further including a buried layer 756 burying each of the mesa-stripe structures 712 on both sides.

In a twelfth implementation, alone or in combination with one or more of the first through eleventh implementations, wherein the mesa-stripe structures 512 further include a pair of third mesa-stripe structures 512C sandwiching the first mesa-stripe structure 512A and the pair of second mesa-stripe structures 512B, the common electrodes 528 further include a pair of third electrodes 528C sandwiching the first electrode 528A and the pair of second electrodes 528B, and the pair of third electrodes 528C are equal in area to or larger than the pair of second electrodes 528B.

In a thirteenth implementation, a semiconductor optical device includes: the semiconductor array device 100 of one or more of the first through twelfth implementations; and a submount 30 on which the semiconductor array device 100 is mounted, the submount 30 including individual terminals 32 and common terminals 36, each of the individual terminals 32 being electrically connected to a corresponding one of the individual electrodes 26, each of the common terminals 36 being electrically connected to a corresponding one of the common electrodes 28.

In a fourteenth implementation, alone or in combination with the thirteenth implementation, wherein the common terminals 36 include a first terminal 36A opposed to and bonded to the first electrode 28A, and a pair of second terminals 36B opposed to and bonded to the respective pair of second electrodes 28B, and each of the pair of second terminals 36B is smaller in area than the first terminal 36A.

In a fifteenth implementation, alone or in combination with one or more of the thirteenth through fourteenth implementations, wherein each of the pair of second terminals 36B is smaller than the first terminal 36A in a bonding area with the corresponding one of the common electrodes 28.

In a sixteenth implementation, alone or in combination with one or more of the thirteenth through fifteenth implementations, further including a wire 34 electrically connecting each of the individual terminals 32 and the corresponding one of the individual electrodes 26, each of the common terminals 36 and the corresponding one of the common electrodes 28 are opposed to and electrically connected to each other.

In a seventeenth implementation, alone or in combination with one or more of the thirteenth through sixteenth implementations, wherein each of the individual terminals 632 and the corresponding one of the individual electrodes 626 are opposed to and electrically connected to each other, and each of the common terminals 636 and the corresponding one of the common electrodes 628 are opposed to and electrically connected to each other.

In an eighteenth implementation, alone or in combination with one or more of the thirteenth through seventeenth implementations, wherein the mesa-stripe structures 512 further include a pair of third mesa-stripe structures 512C sandwiching the first mesa-stripe structure 512A and the pair of second mesa-stripe structures 512B, the common electrodes 528 further include a pair of third electrodes 528C sandwiching the first electrode 528A and the pair of second electrodes 528B, each of the pair of third electrodes 528C is larger in area than either of the pair of second electrodes 528B, and the individual terminals 532 are not electrically connected to the active layer 516 of either of the pair of third mesa-stripe structures 512C.

In a nineteenth implementation, alone or in combination with one or more of the thirteenth through eighteenth implementations, wherein the common terminals 536 include a first terminal 536A opposed to and bonded to the first electrode 528A, a pair of second terminals 536B opposed to and bonded to the respective pair of second electrodes 528B, and third terminals 536C opposed to and bonded to the respective pair of third electrodes 528C.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor array device comprising:
a semiconductor substrate;
mesa-stripe structures that each extend in a first direction, are arranged at equal intervals adjacent to each other in a second direction perpendicular to the first direction, and each include an active layer electrically connected to the semiconductor substrate;
individual electrodes that are arranged adjacent to each other in the second direction, and are each electrically connected to the active layer of a corresponding one of the mesa-stripe structures; and
common electrodes that are arranged adjacent to each other in the second direction, and are each electrically connected to the semiconductor substrate, wherein:
the mesa-stripe structures including a first mesa-stripe structure and a pair of second mesa-stripe structures, the pair of second mesa-stripe structures sandwiching the first mesa-stripe structure,
the common electrodes including a first electrode and a pair of second electrodes, the pair of second electrodes sandwiching the first electrode,
the first electrode being closest to the first mesa-stripe structure among the mesa-stripe structures,
each of the pair of second electrodes being closest to a corresponding one of the pair of second mesa-stripe structures among the mesa-stripe structures,
each of the pair of second electrodes being smaller in area than the first electrode.

2. The semiconductor array device of claim 1, wherein
each of the pair of second electrodes is equal in length to the first electrode in the first direction, and
each of the pair of second electrodes is smaller in width than the first electrode in the second direction.

3. The semiconductor array device of claim 1, wherein the individual electrodes are equal in area to each other.

4. The semiconductor array device of claim 1, wherein
the first mesa-stripe structure includes a plurality of first mesa-stripe structures,
the first electrode is one first electrode,
the one first electrode includes a plurality of sections equal in size to each other and equal in number to the first mesa-stripe structures, and
each of the pair of second electrodes is smaller in area than each of the portions.

5. The semiconductor array device of claim 1, wherein the first mesa-stripe structure includes a plurality of first mesa-stripe structures, and
the first electrode includes a plurality of first electrodes, separated.

6. The semiconductor array device of claim 5, wherein the first electrodes are equal in area to each other.

7. The semiconductor array device of claim 5, wherein a closer one of the first electrodes to either of the pair of second electrodes is smaller in area.

8. The semiconductor array device of claim 1, wherein
the mesa-stripe structures are on an upper surface of the semiconductor substrate,
the common electrodes are on a lower surface of the semiconductor substrate,
the first electrode overlaps with the first mesa-stripe structure, and
each of the pair of second electrodes overlaps with a closer one of the pair of second mesa-stripe structures.

9. The semiconductor array device of claim 1, wherein
the mesa-stripe structures are on the upper surface of the semiconductor substrate,
the common electrodes are in contact with the upper surface of the semiconductor substrate,
the first electrode is adjacent to the first mesa-stripe structure, and
each of the pair of second electrodes is adjacent to a closer one of the pair of second mesa-stripe structures.

10. The semiconductor array device of claim 9, wherein
each of the common electrodes bends upward from the upper surface of the semiconductor substrate and includes a bottom portion in contact with the upper surface and a top portion at a higher position than the bottom portion, and
the top portion of each of the pair of second electrodes is smaller in area than the top portion of the first electrode.

11. The semiconductor array device of claim 1, further comprising a buried layer burying each of the mesa-stripe structures on both sides.

12. The semiconductor array device of claim 1, wherein
the mesa-stripe structures further include a pair of third mesa-stripe structures sandwiching the first mesa-stripe structure and the pair of second mesa-stripe structures,
the common electrodes further include a pair of third electrodes sandwiching the first electrode and the pair of second electrodes, and
the pair of third electrodes are equal in area to or larger than the pair of second electrodes.

13. A semiconductor optical device comprising:
the semiconductor array device of claim 1; and
a submount on which the semiconductor array device is mounted,
the submount individual terminals and common terminals,
each of the individual terminals being electrically connected to a corresponding one of the individual electrodes,
each of the common terminals being electrically connected to a corresponding one of the common electrodes.

14. The semiconductor optical device of claim 13, wherein
the common terminals include a first terminal opposed to and bonded to the first electrode, and a pair of second terminals opposed to and bonded to the respective pair of second electrodes, and
each of the pair of second terminals is smaller in area than the first terminal.

15. The semiconductor optical device of claim 14, wherein each of the pair of second terminals is smaller than the first terminal in a bonding area with the corresponding one of the common electrodes.

16. The semiconductor optical device of claim 13, further comprising a wire electrically connecting each of the individual terminals and the corresponding one of the individual electrodes,
each of the common terminals and the corresponding one of the common electrodes are opposed to and electrically connected to each other.

17. The semiconductor optical device of claim 13, wherein
each of the individual terminals and the corresponding one of the individual electrodes are opposed to and electrically connected to each other, and
each of the common terminals and the corresponding one of the common electrodes are opposed to and electrically connected to each other.

18. The semiconductor optical device of claim 13, wherein
the mesa-stripe structures further include a pair of third mesa-stripe structures sandwiching the first mesa-stripe structure and the pair of second mesa-stripe structures,
the common electrodes further include a pair of third electrodes sandwiching the first electrode and the pair of second electrodes,
each of the pair of third electrodes is larger in area than either of the pair of second electrodes, and
the individual terminals are not electrically connected to the active layer of either of the pair of third mesa-stripe structures.

19. The semiconductor optical device of claim 18, wherein the common terminals include a first terminal opposed to and bonded to the first electrode, a pair of second terminals opposed to and bonded to the respective pair of second electrodes, and third terminals opposed to and bonded to the respective pair of third electrodes.
